(19) United States
(12) Patent Application Publication
(10) Pub. No.: US 2026/0363130 A1
(43) Pub. Date: Nov. 12, 2026

(54) ENCAPSULATION STRUCTURE

(71) Applicant: AAC Microtech (Changzhou) Co., Ltd., Changzhou City (CN)

(72) Inventor: Bingyue Bai, Changzhou (CN)

(21) Appl. No.: 19/340,848

(22) Filed: Sep. 25, 2025

Related U.S. Application Data
(63) Continuation of application No. PCT/CN2025/093155, filed on May 7, 2025.

(51) Int. Cl. H10W 74/10; H10W 40/73

(52) U.S. Cl. CPC H10W 74/114; H10W 40/73

(57) ABSTRACT

An encapsulation structure, including: a circuit board; a vapor chamber arranged on a first surface of the circuit board, the vapor chamber and the circuit board hermetically defining an accommodating cavity; a chip connected to the circuit board and accommodated in the accommodating cavity, a gap being formed between the chip and the vapor chamber; and a thermal interface material filling in the gap and used for transferring heat generated by the chip to the vapor chamber. A heat conduction effect is effectively improved while the chip is effectively encapsulated.

### TECHNICAL FIELD

The present disclosure relates to the field of electronic device encapsulation, and in particular, to an encapsulation structure.

### Background

Currently, how to realize heat dissipation of a chip is a difficult problem in use of the chip. Since the chip is encapsulated in a copper cover, a large amount of heat is accumulated inside the chip and in the encapsulation cover around the chip, so that the heat is difficult to be conducted outside.

Therefore, it is desirable to provide an encapsulation structure with fast heat conduction.

### SUMMARY

An objective of the present disclosure is to provide an encapsulation structure, which solves the technical problem that an encapsulation structure in the prior art has difficulty in heat conduction.

The technical solutions of the present disclosure are as follows.

The present disclosure provides an encapsulation structure, including: a circuit board; a vapor chamber arranged on a first surface of the circuit board, the vapor chamber and the circuit board hermetically defining an accommodating cavity; a chip connected to the circuit board and accommodated in the accommodating cavity, a gap being formed between the chip and the vapor chamber; and a thermal interface material filling in the gap and used for transferring heat generated by the chip to the vapor chamber.

As an improvement, the encapsulation structure further includes an adhesive, and the adhesive is used for fixing the vapor chamber to the first surface.

As an improvement, a second surface of the vapor chamber is arranged to face the first surface of the circuit board; the second surface is provided with a first concave portion, the first concave portion is recessed towards the vapor chamber relative to the second surface, and a surface of the first concave portion and the first surface jointly define the accommodating cavity; the second surface is further provided with a second concave portion, the second concave portion is recessed towards the vapor chamber relative to the second surface, and the second concave portion surrounds the first concave portion and has a distance from the first concave portion; and the adhesive fills between a surface of the second concave portion and the first surface.

As an improvement, the adhesive is glue.

As an improvement, a side of the first concave portion, the second surface and a side of the second concave portion define a convex portion, and the convex portion abuts against the first surface.

As an improvement, the vapor chamber is made of stainless steel.

As an improvement, the first concave portion is arranged at a middle of the vapor chamber.

As an improvement, the thermal interface material fully fills in the gap.

As an improvement, the chip includes a third surface facing the first surface and a fourth surface facing away the third surface, and the fourth surface is not in contact with the vapor chamber.

As an improvement, the encapsulation structure includes one or more chips.

### BRIEF DESCRIPTION OF DRAWINGS

FIG. 1 is a schematic sectional diagram of an encapsulation structure according to an embodiment of the present disclosure.

### DESCRIPTION OF EMBODIMENTS

The present disclosure is further described below with reference to the drawings and the embodiments.

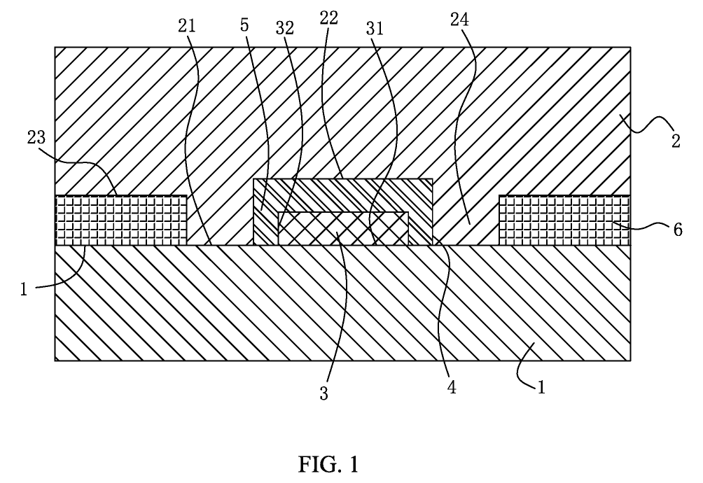

An embodiment of the present disclosure provides an encapsulation structure, including a circuit board 1, a vapor chamber 2, and a chip 3, as shown in FIG. 1. The vapor chamber 2 is arranged on a first surface 11 of the circuit board 1, and the vapor chamber 2 and the circuit board 1 hermetically define an accommodating cavity 4. The chip 3 is connected to the circuit board 1, the chip 3 is accommodated in the accommodating cavity 4, and a gap is formed between the chip 3 and the vapor chamber 2. A thermal interface material 5 fills in the gap between the chip 3 and the vapor chamber 2, and the thermal interface material 5 is used for transferring heat generated by the chip 3 to the vapor chamber 2.

In this embodiment, the chip 3 is encapsulated by the vapor chamber 2, and the gap between the chip 3 and the vapor chamber 2 is filled with the thermal interface material 5 (TIM). The thermal interface material 5 can reduce heat transfer contact resistance and improve a heat dissipation performance, thereby sufficiently transferring the heat generated by the chip 3 to the vapor chamber 2. The vapor chamber 2 has good transverse heat conductivity, so that the heat generated by the chip 3 can be fully and effectively conducted to the outside of the encapsulation structure through the thermal interface material 5 and the vapor chamber 2 in sequence, the heat is prevented from being concentrated in the chip 3 and the encapsulation structure around the chip 3, therefore a heat conduction effect is effectively improved while the chip 3 is effectively encapsulated.

In some embodiments, referring to FIG. 1, the encapsulation structure further includes an adhesive 6, and the adhesive 6 is used for fixing the vapor chamber 2 to the first surface 11.

In this embodiment, the vapor chamber 2 is fixed to the circuit board 1 by the adhesive 6, so that an operation is convenient, and damage of assembly to the vapor chamber 2 and the circuit board 1 can be effectively reduced.

As an example, the adhesive 6 may be glue, which is not only convenient to use, high in safety, but also low in cost.

In some embodiments, the adhesive 6 is arranged around the accommodating cavity 4. That is, the adhesive 6 is applied to a whole periphery of the accommodating cavity 4, and surrounds the accommodating cavity 4, and the adhesive 6 not only can uniformly and effectively bond and fix the vapor chamber 2 and the circuit board 1, but also can play a role in further sealing the accommodating cavity 4, thereby further improving an encapsulation effect.

As an embodiment, referring to FIG. 1, a second surface 21 of the vapor chamber 2 is arranged to face the first surface 11 of the circuit board 1. The second surface 21 is provided with a first concave portion 22, the first concave portion 22 is recessed towards the vapor chamber 2 relative to the second surface 21, and a surface of the first concave portion 22 and the first surface 11 jointly define the accommodating cavity 4. The second surface 21 is further provided with a second concave portion 23, the second concave portion 23 is recessed towards the vapor chamber 2 relative to the second surface 21, the second concave portion 23 surrounds the first concave portion 22, and a distance is present between the first concave portion 22 and the second concave portion 23. The adhesive 6 is packed between a surface of the second concave portion 22 and the first surface 11.

In this embodiment, the adhesive 6 is packed between the surface of the second concave portion 23 and the first surface 11, which can avoid that when the vapor chamber 2 is fixed onto the circuit board 1, the vapor chamber 2 and the circuit board 1 press the adhesive 6 to cause the adhesive 6 to flow to reduce a thickness of the adhesive 6, thus effectively guaranteeing a bonding effect. Moreover, a distance is formed between the first concave portion 22 and the second concave portion 23, so that the adhesive 6 can be prevented from entering the accommodating cavity 4, thereby better protecting the chip 3.

As an example, the second concave portion 23 may be of a closed ring structure, that is, the second concave portion 23 is of a complete ring structure, and the adhesive 6 fully fills between the surface of the second concave portion 23 and the first surface 11, thereby further improving a fixing effect and a sealing effect.

It should be noted that, in other embodiments, the vapor chamber 2 may be fixed on the circuit board 1 in other manners, and the manner may be set according to actual situations, and is not repeated herein.

As an embodiment, referring to FIG. 1, a side of the first concave portion 22, the second surface 21 and a side of the second concave portion 23 jointly define a convex portion 24, and the convex portion 24 abuts against the first surface 11.

In this embodiment, the side of the first concave portion 22, the second surface 21 and the side of the second concave portion 23 jointly define the convex portion 24, and the second surface 21 forming the concave portion 24 abuts against the first surface 11, which can improve a hermetic effect, thereby better protecting the chip 3 and further improving the encapsulation effect on the chip 3. Moreover, the convex portion 24 is located between the first concave portion 22 and the second concave portion 23, so that the adhesive 6 can be further prevented from entering the first concave portion 22, thereby effectively protecting the chip 3.

In some embodiments, the vapor chamber 2 may be a three dimensional vapor chamber (3DVC). As an example, the vapor chamber 2 may include a plate body and a tube connected to the plate body, a cavity of the plate body is communicated with a cavity of the tube, and the plate body and the circuit board 1 hermetically define the accommodating cavity 4. It should be noted that the 3DVC in this embodiment may be the prior art, and is not repeated herein. It can be understood that, in other embodiments, the vapor chamber may be a vapor chamber without a tube, which may be configured according to actual situations, and no limitation is made herein.

In some embodiments, the vapor chamber 2 is made of stainless steel, has good corrosion resistance, good high temperature resistance, good wear resistance and a good sealing performance, and can protect the chip 3 more effectively, it is not required to add a strength-enhancing material, an anti-oxidation material, or other protection structure inside or outside the vapor chamber 2, the structure of the vapor chamber 2 can be effectively simplified, and the service life of the encapsulation structure can be prolonged.

In an embodiment, the first concave portion 22 is arranged at the middle of the vapor chamber 2, so that not only a heat conduction effect is better, and more uniform and faster heat conduction can be realized, but also the chip 3 can be better protected.

In an embodiment, referring to FIG. 1, a surface of the chip 3 is divided into a third surface 31 and a fourth surface 32, and the fourth surface 32 is a surface region facing away the third surface 31. The third surface 31 is connected to the first surface 11, and the fourth surface 32 is not in contact with the vapor chamber 2.

In some embodiments, referring to FIG. 1, the thermal interface material 5 fully fills in the gap between the chip 3 and a surface of the accommodating cavity 4, so as to more uniformly and rapidly conduct the heat generated by the chip 3 to the vapor chamber 2.

In an embodiment, the chip 3 is of a square structure and includes six surfaces, one of the six surfaces is arranged to face the circuit board 1, and the other five surfaces are arranged to face the surface of the first concave portion 22 of the vapor chamber 2, gaps are formed between the other five surfaces and the vapor chamber 2, and the thermal interface material 5 fills all the gaps, thereby increasing a heat conducting area as much as possible and conducting the heat more rapidly and uniformly.

In some embodiments, the encapsulation structure may include one chip 3.

In some other embodiments, the encapsulation structure may include a plurality of chips 3, all of which may be encapsulated in a same accommodating cavity 4 or in different accommodating cavities 4, which may be configured according to actual situations and is not repeated herein.

In some embodiments, the circuit board 1 may be a printed circuit board (PCB). In other embodiments, the circuit board 1 may be other type of circuit board, which may be configured according to actual situations and is not repeated herein.

The above description merely described some embodiments of the present disclosure, and it should be noted that improvements can be made by those of ordinary skill in the art without departing from the concept of the present disclosure, and all of them shall fall within a scope of the present disclosure.

What is claimed is:

1. An encapsulation structure, comprising:
a circuit board;
a vapor chamber arranged on a first surface of the circuit board, the vapor chamber and the circuit board hermetically defining an accommodating cavity;
a chip connected to the circuit board and accommodated in the accommodating cavity, a gap being formed between the chip and the vapor chamber; and
a thermal interface material filling in the gap and used for transferring heat generated by the chip to the vapor chamber.

2. The encapsulation structure as described in claim 1, wherein the encapsulation structure further comprises an adhesive, and the adhesive is used for fixing the vapor chamber to the first surface.

3. The encapsulation structure as described in claim 2, wherein a second surface of the vapor chamber is arranged to face the first surface of the circuit board;
the second surface is provided with a first concave portion, the first concave portion is recessed towards the vapor chamber relative to the second surface, and a surface of the first concave portion and the first surface jointly define the accommodating cavity;
the second surface is further provided with a second concave portion, the second concave portion is recessed towards the vapor chamber relative to the second surface, and the second concave portion surrounds the first concave portion and has a distance from the first concave portion; and
the adhesive fills between a surface of the second concave portion and the first surface.

4. The encapsulation structure as described in claim 2, wherein the adhesive is glue.

5. The encapsulation structure as described in claim 3, wherein a side of the first concave portion, the second surface and a side of the second concave portion define a convex portion, and the convex portion abuts against the first surface.

6. The encapsulation structure as described in claim 1, wherein the vapor chamber is made of stainless steel.

7. The encapsulation structure as described in claim 3, wherein the first concave portion is arranged at a middle of the vapor chamber.

8. The encapsulation structure as described in claim 1, wherein the thermal interface material fully fills in the gap.

9. The encapsulation structure as described in claim 8, wherein the chip comprises a third surface facing the first surface and a fourth surface facing away the third surface, and the fourth surface is not in contact with the vapor chamber.

10. The encapsulation structure as described in claim 1, wherein the encapsulation structure comprises one or more chips.
